(19) United States
(12) Patent Application Publication
(10) Pub. No.: US 2008/0061409 A1
(43) Pub. Date: Mar. 13, 2008

(54) Micro electro-mechanical system module package

(75) Inventors: Tzu-Yin Yen, Taichung County (TW); Cung-Mao Yeh, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/710,546

(22) Filed: Feb. 26, 2007

(30) Foreign Application Priority Data
Sep. 8, 2006 (TW) 95216091

(51) Int. Cl. H01L 23/495; H01L 23/48

(52) U.S. Cl. 257/666; 257/702; 257/E23.01

(57) ABSTRACT

A MEMS module package includes a substrate, a silicon chip attached on the substrate and having an active zone and an inactive zone surrounding around the active zone, a plurality of bonding wires electrically connected the silicon chip and the substrate, and an encapsulant formed between the inactive zone of the silicon chip and the substrate to encapsulate the inactive zone of the silicon, the bonding wires and a part of the substrate in such a manner that the active zone of the silicon chip is exposed outside the encapsulant. The MEMS module package uses a molding technique to substitute for the conventional cap package, thereby simplifying the packaging procedure and saving much the cost of manufacturing.

### BACKGROUND OF THE INVENTION

1. Field of the Invention

The present invention relates to the micro electromechanical systems (MEMS) and more specifically, to a MEMS module package.

2. Description of the Related Art

The micro electro-mechanical system (hereinafter referred to as ‘MEMS’) technology has been intensively used in different fields for different applications. MEMS is the integration of mechanical elements, sensors, actuators, and electronics on a common silicon substrate through a micro fabrication technology. It allows the development of smart products. The application of MEMS technology greatly improves the performance, quality, reliability and added values of small-sized electronic products. Further, to ensure high performance, the package of a MEMS module must consider mechanical support strength, environment factors (for example, humility or corrosive substances), electric connection, and heat resistance.

Conventionally, cap package technology is employed for packaging MEMS module. FIG. 1 shows a MEMS module package according to the prior art. According to this design, a cap 2 is capped on a substrate 1 to enclose a silicon chip 3 on the substrate 1. The use of cap package technology in this MEMS module package greatly complicates the manufacturing procedure, resulting in a high manufacturing cost. Further, due to low work efficiency, cap package technology is not suitable for making a MEMS package having its silicon chip exposed to the outside.

Therefore, it is desirable to provide a MEMS module package that eliminates the aforesaid drawbacks.

### SUMMARY OF THE INVENTION

It is one objective of the present invention to provide a MEMS module package, which simplifies the packaging procedure and saves much the cost.

To achieve this objective of the present invention, the MEMS module package comprises a substrate, a silicon chip attached on the substrate and having an active zone and an inactive zone surrounding around the active zone, a plurality of bonding wires electrically connected between the silicon chip and the substrate, and an encapsulant form between the inactive zone and the substrate to encapsulate the inactive zone, the bonding wires and a part of the substrate in such a manner that the active zone of the silicon chip is exposed outside the encapsulant.

Because the MEMS module package of the present invention uses a molding technique to encapsulate the inactive zone instead of the conventional cap package technique, the invention simplifies the packaging procedure and saves much the cost. Further, the invention is applicable to the exposed type of MEMS module package. Therefore, the invention shows superior applicability over the prior art design.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic drawing showing a MEMS module package according to the prior art;

FIG. 2 is a schematic drawing showing that a silicon chip is attached on a substrate according to a first preferred embodiment of the present invention;

FIG. 3 is a schematic drawing showing that the silicon chip and the substrate are electrically connected by bonding wires according to the first preferred embodiment of the present invention;

FIG. 4 is a schematic drawing showing the MEMS module package according to the first preferred embodiment of the present invention;

FIG. 5 is a schematic drawing showing a MEMS module package in accordance with a second preferred embodiment of the present invention;

FIG. 6 is a schematic drawing showing the relationship of a silicon chip and a lead frame of a MEMS module package in accordance with a third preferred embodiment of the present invention;

FIG. 7 is a schematic drawing showing that the silicon chip and the lead frame are electrically connected by bonding wires in accordance with the third preferred embodiment of the present invention;

FIG. 8 is a schematic drawing showing that an encapsulant is applied to encapsulate the bonding wires and a part of the lead frame and a part of the chip in accordance with the third preferred embodiment of the present invention, and

FIG. 9 is a schematic drawing showing the MEMS module package in accordance with the third preferred embodiment of the present invention.

### DETAILED DESCRIPTION OF THE INVENTION

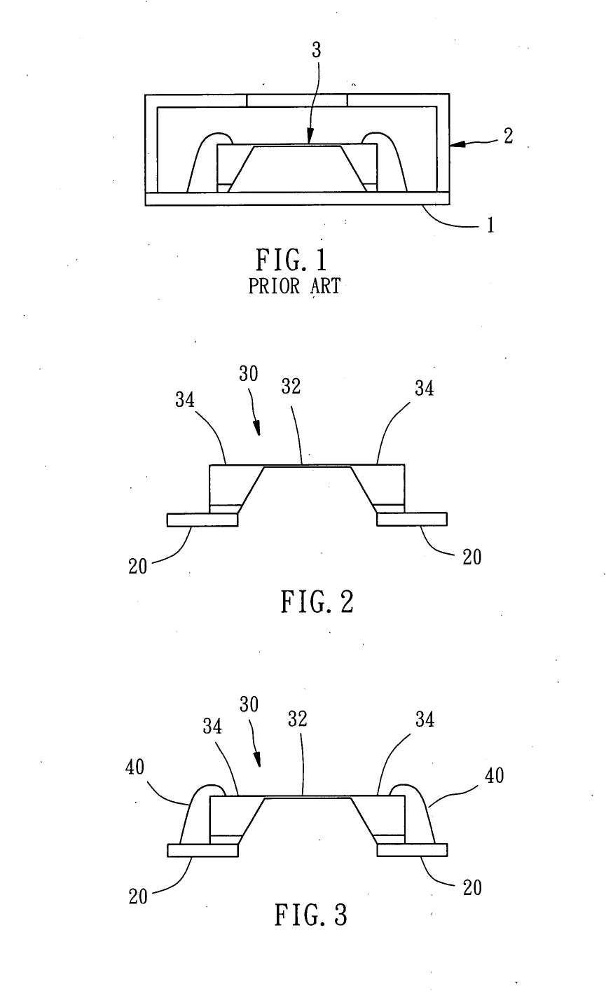

As shown in FIGS. 2-4, a MEMS module package 10 in accordance with a first preferred embodiment of the present invention comprises a substrate 20, a silicon chip 30, a plurality of bonding wires 40 and an encapsulant 50.

The substrate 20 can be an epoxy-based substrate, organic fiber glass substrate, glass fiber board, polyphenylene either-based substrate, or preferably ceramic substrate. Further, the substrate 20 can be a stacked structure.

The silicon chip 30 is attached on the substrate 20, having an active zone 32 and an inactive zone 34. The active zone 32 is a thin film structure disposed at the center of the silicon chip 30. The inactive zone 34 has a thickness greater than the active zone 32, and is arranged surrounding around the active zone 32.

The bonding wires 40 are electrically connected between the substrate 20 and the top side of the inactive zone 34 of the silicon chip 30.

The encapsulant 50 is formed by the molding technique on the substrate 20 and the inactive zone 34 of the silicon chip 30 to encapsulate a part of the substrate 20, the inactive zone 34 and the bonding wires 40.

Referring to FIGS. 2-4 again, the packaging method of the MEMS module package 10 in accordance with the first embodiment of the present invention includes the following steps.

a) Fixedly attach the inactive zone 34 of the silicon chip 30 to the top side of the substrate 20 as shown in FIG. 2.

b) Electrically connect the bonding wires 40 to the substrate 20 and the top side of the inactive zone 34 of the silicon chip 30 by the wire bonding technology, as shown in FIG. 3.

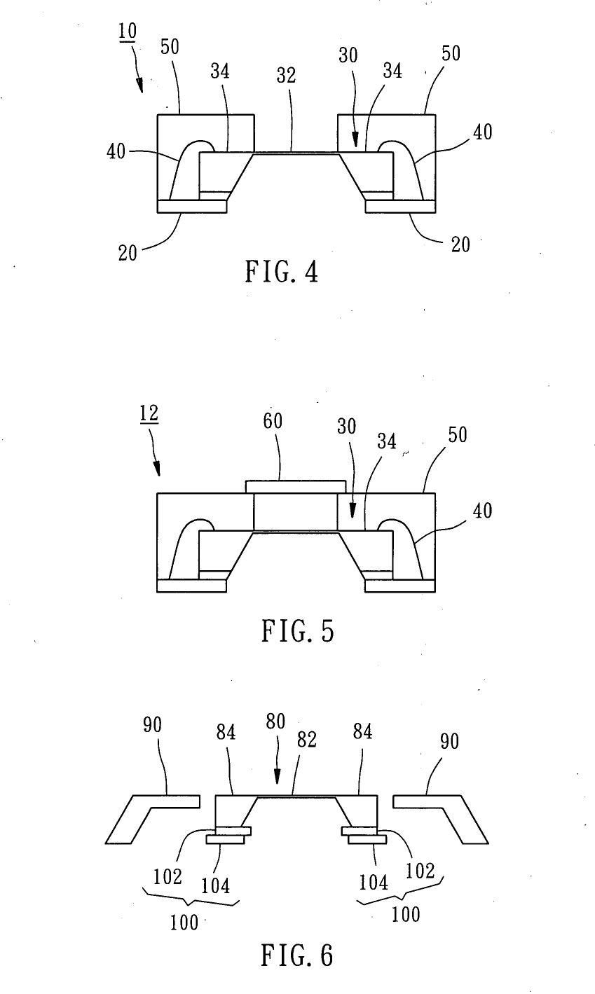

c) Encapsulate the inactive zone 34 of the silicon chip 30, a part of the substrate 20 and the bonding wires 40 by a molding compound by means of a molding technique, leaving the active zone 32 to be exposed to the outside of the encapsulant 50 thus molded as shown in FIG. 4.

As stated above, the MEMS module package 10 uses a molding technique to encapsulate the inactive zone 34. Structurally speaking, the invention is suitable for the environment where the active zone 32 has to be exposed to the outside for measurement. The invention shows superior applicability over the prior art design. Further, the invention simplifies the packaging procedure and saves much the processing time, thereby greatly reducing the cost.

FIG. 5 shows a MEMS module package 12 in accordance with a second preferred embodiment of the present invention. Similar to the aforesaid first embodiment, this second embodiment also comprises a substrate 20, a silicon chip 30, a plurality of bonding wires 40 and an encapsulant 50. This second embodiment further comprises a protection film 60 provided at the top side of the encapsulant 50 to shade the active zone 32 of the silicon chip 30, giving protection to the active zone 32 of the silicon chip 30.

FIG. 9 shows a MEMS module package 70 in accordance with a third preferred embodiment of the present invention. According to this embodiment, the MEMS module package 70 comprises a silicon chip 80, a leadframe having a plurality of leads 90, a conducting layer 100, a plurality of bonding wires 110, an encapsulant 120, and a protection film 130.

As shown in FIGS. 6-9, the silicon chip 80 has an active zone 82 and an inactive zone 84. The active zone 82 is a thin film structure disposed at the center of the silicon chip 80. The inactive zone 84 has a thickness greater than the active zone 82, and is arranged surrounding around the active zone 82.

The leads 90 of the leadframe are arranged around the silicon chip 80.

The conducting layer 100 is provided at the bottom side of the silicon chip 80, comprising a layer of ITO (Indium Tin Oxide) conductive glass member 102 and a plurality of solder pads 104. The layer of ITO conductive glass member 102 is disposed at the top side of the conducting layer 100 and electrically connected to the bottom side of the inactive zone 84 of the silicon chip 80. The solder pads 104 are disposed at the bottom side of the conducting layer 100 and respectively electrically connected to the ITO conductive glass member 102, for enabling the conducting layer 100 to electrically connect the silicon chip 80 to other devices (not shown).

The bonding wires 110 are respectively electrically connected between the top side of the inactive zone 84 of the silicon chip 80 and the lead frames 90.

The encapsulant 120 is molded on the silicon chip 80 and the leadframe to encapsulate the inactive zone 84 of the silicon chip 80, a part of each of the leads 90, the bonding wires 110 and a part of the conducting layer 100.

The protection film 130 is provided at the top side of the encapsulant 120 to shade the active zone 82 of the silicon chip 80, giving protection to the active zone 82 of the silicon chip 80.

Referring to FIGS. 6-9 again, the packaging method of the MEMS module package 70 in accordance with the third preferred embodiment of the present invention includes the following steps.

a) Bond the conducting layer 100 to the bottom side of the silicon chip 80 and then arrange the silicon chip 80 and the leads 90 of the leadframe subject to a predetermined position arrangement as shown in FIG. 6.

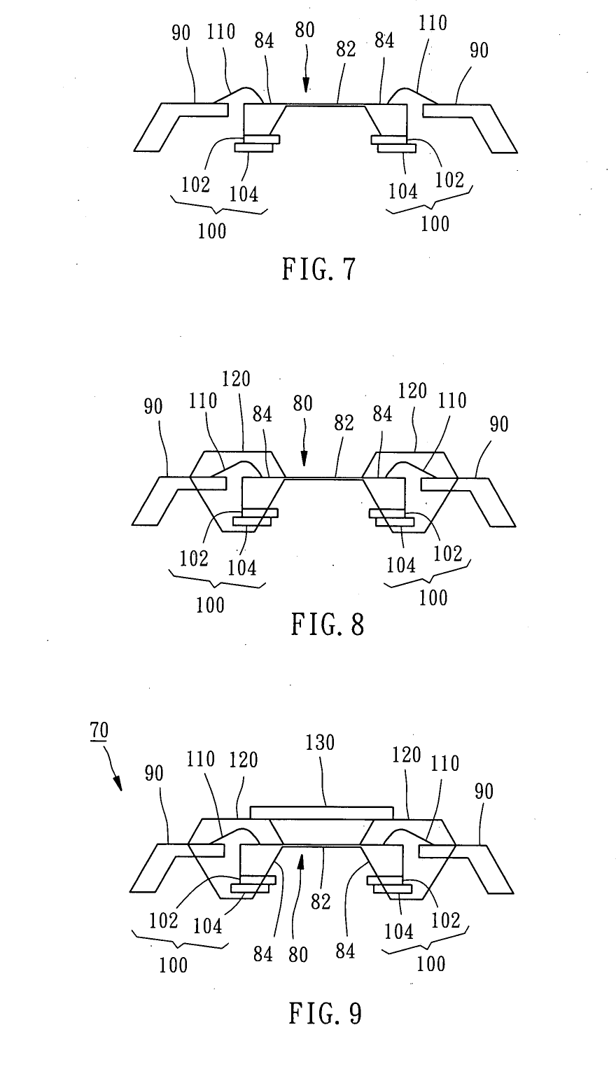

b) Electrically connect the bonding wires 110 to the top side of the inactive zone 84 of the silicon chip 80 and the respective leads 90 by wire bonding technology as shown in FIG. 7.

c) Encapsulate the inactive zone 84 of the silicon chip 80, a part of the leads 90, a part of the conducting layer 100 and the bonding wires 40 with a molding compound by means of a molding technique, leaving the active zone 82 to be exposed to the outside of the encapsulant 120 thus molded as shown in FIG. 8.

d) Form the protective film layer 130 on the top side of the encapsulant 120 to shade the active zone 82 of the silicon chip 80 as shown in FIG. 9.

Unlike the aforesaid first embodiment in which the MEMS module package 10 is electrically connectable to external devices by means of its substrate 20, the MEMS module package 70 according to this third embodiment is electrically connectable to external devices by means of its leads 90. However, this third embodiment achieves the same effects of the aforesaid first and second embodiments.

As indicated above, the invention uses a molding technique to substitute for the cap package of the prior art design, simplifying the packaging procedure and saving much the processing time and cost. Further, the invention is applicable to exposed type MEMS module packages. When compared to the prior art design, the invention shows superior applicability.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A MEMS module package comprising:
a substrate;
a silicon chip attached on the substrate and having an active zone and an inactive zone surrounding around the active zone;
a plurality of bonding wires electrically connected the silicon chip and the substrate; and
an encapsulant formed between the inactive zone of the silicon chip and the substrate to encapsulate the inactive zone of the silicon chip, the bonding wires and a part of the substrate.

2. The MEMS module package as claimed in claim 1, further comprising a conducting layer provided between the substrate and the silicon chip for electrically connecting the substrate and the silicon chip.

3. The MEMS module package as claimed in claim 2, wherein the conducting layer comprises a layer of ITO conductive glass member provided between the substrate and the silicon chip for electrically connecting the substrate and the silicon chip.

4. The MEMS module package as claimed in claim 2, wherein the conducting layer comprises a plurality of solder pads provided between the substrate and the silicon chip for electrically connecting the substrate and the silicon chip.

5. The MEMS module package as claimed in claim 1, wherein the active zone is a thin film structure located at a center of the silicon chip.

6. The MEMS module package as claimed in claim 1, further comprising a protective film bonded to the encapsulant to shade the active zone.

7. The MEMS module package as claimed in claim 1, wherein the substrate is an epoxy-based substrate, organic fiber glass substrate, glass fiber board, polyphenylene either-based substrate or ceramic substrate.

8. The MEMS module package as claimed in claim 1, wherein the substrate is a stacked structure.

9. A MEMS module package comprising:
a silicon chip having an active zone and an inactive zone surrounding around the active zone;
a leadframe having a plurality of leads arranged around the silicon chip;
a plurality of bonding wires electrically connected the silicon chip and the leads of the leadframe; and
an encapsulant formed between the inactive zone of the silicon chip and the leads of the leadframe to encapsulate the inactive zone, the bonding wires and a part of each of the leads.

10. The MEMS module package as claimed in claim 9, further comprising a conducting layer electrically connected to a bottom side of the silicon chip.

11. The MEMS module package as claimed in claim 10, wherein the conducting layer comprises a layer of ITO conductive glass member electrically connected with the silicon chip.

12. The MEMS module package as claimed in claim 10, wherein the conducting layer comprises a plurality of solder pads electrically connected with the silicon chip.

13. The MEMS module package as claimed in claim 9, wherein the active zone is a thin film structure located at a center of the silicon chip.

14. The MEMS module package as claimed in claim 9, further comprising a protective film bonded to the encapsulant to shade the active zone.
